(19) United States
(12) Patent Application Publication
(10) Pub. No.: US 2002/0053901 A1
(43) Pub. Date: May 9, 2002

(54) Linear inductive fluid level sensor

(76) Inventors: Lance Ronald Strayer, Clarkston, MI (US); Michael D. Lutton, Grand Blanc, MI (US); Chris C. Begley, Ortonville, MI (US); Robert J. Byram, Gramd Blanc, MI (US); Daniel A. Crawford, Burton, MI (US)

Correspondence Address: VINCENT A. CICHOSZ, DELPHI TECHNOLOGIES, INC., Legal Staff, Mail Code: 480-414-420, P.O. Box 5052, Troy, MI, 48007-5052, US

(21) Appl. No.: 09/950,332

(22) Filed: Sep. 11, 2001

Related U.S. Application Data
(60) Provisional application No. 60/238,180, filed on Oct. 5, 2000.

(51) Int. Cl. G01R 1/20

(52) U.S. Cl. 324/146

(57) ABSTRACT

An inductive coil is disclosed comprising a bobbin and a coil encircling the bobbin. The coil encircling the bobbin defines at least one layer of coil extending over a first portion of the bobbin. At least one other layer of the coil extends over less than the first portion of the bobbin. A method of constructing a coil sensor including a bobbin comprises beginning at a first location on the bobbin, encircling the bobbin with a coil defining thereby at least one layer of the coil, the at least one layer extending over a first portion of the bobbin; wherein at least one other layer of the coil extends over a second portion of the bobbin less than the first portion of the bobbin.

### RELATED APPLICATIONS

This application claims the benefit of U.S. Provisional Patent Application No. 60/238,180 filed Oct. 5, 2000, which is incorporated herein by reference.

### TECHNICAL FIELD

This disclosure relates to fluid level sensors and in particular to inductive coils therein having a staggered number of turns.

### BACKGROUND

Current automotive fuel level sensors are comprised of a resistive ink on a ceramic substrate to create a variable resistor or potentiometer. A floatation device and a float arm are attached to a wiper that has electrical contacts that ride along the resistive ink. The resistance value of the circuit changes as the contacts move along the resistive ink and is indicative of fuel level.

However, the resistive value of the circuit can increase due to oxidation at the ink/contact interface. The likelihood of oxidation is dependent upon a combination of factors including: ink composition, contact composition, contact load force, contact geometry, voltage potential across the contacts, fuel composition, temperature and moisture content.

Because of the uncertainty of future fuel formulations and their effect upon oxidation formation, it is desirable to provide a contact-less fuel level sensor having long-term durability.

### SUMMARY OF THE INVENTION

This disclosure utilizes an inductive coil to measure the fuel level in an automotive fuel tank. The electronics to drive the circuit are located outside of the fuel tank. This simplifies the winding process but provides a non-linear change in the inductance of the inductive sensor as the position of a magnetic core within the coil varies. An arced coil is utilized to minimize the space required for the sensor inside the fuel tank. However, this invention would apply similarly to a straight coil. By using a staggered coil design, the change in the inductance of the coil sensor as the core position within the coil varies, can be linearized. This allows the circuit reading the effective inductance to be simplified since signal processing is not required to linearize the signal for practical use. The staggered coil uses a greater number of turns where the core first enters the coil in order to boost the effective inductance of the coil sensor and to allow less insertion distance where the effective inductance is non-linear. This has the added benefit of shortening the overall length of the coil. A linear output of approximately 80 degrees is the desired output, with a total travel of approximately 140 degrees.

An inductive coil is disclosed comprising a bobbin and a coil encircling the bobbin. The coil encircling the bobbin defines at least one layer of coil extending over a first portion of the bobbin. At least one other layer of the coil extends over less than the first portion of the bobbin. A method of constructing a coil sensor including a bobbin comprises beginning at a first location on the bobbin, encircling the bobbin with a coil defining thereby at least one layer of the coil, the at least one layer extending over a first portion of the bobbin; wherein at least one other layer of the coil extends over a second portion of the bobbin less than the first portion of the bobbin.

### BRIEF DESCRIPTION OF THE DRAWINGS

FIG. 1 is a three dimensional perspective view of a linear inductive fuel sensor;

FIG. 2 is a graphical representation depicting the relative timing of a square wave driving pulse voltage, Vₚᵤₗₛₑ, and the resultant voltage, V_{coil}, across the coil sensor;

FIG. 3 is a schematic diagram of an exemplary embodiment of an electric circuit for determining the fuel level in a container including a model of a coil sensor;

FIG. 4 is a graphical representation of the number of layers of coil in a linear inductive fuel sensor as a function of the angular position of the core within an arced coil in a straight wound coil and a staggered wound coil;

FIG. 5 is a graphical representation of the output voltage of a linear inductive fuel sensor as a function of the angular position of the core within an arced coil in a straight wound coil and a staggered wound coil;

FIG. 6 is a graphical representation of the linearization of the output voltage of the linear inductive fuel sensor of FIG. 5 for a straight wound coil and a staggered wound coil;

FIG. 7 is a representation of an arced coil utilizing a staggered coil winding;

FIGS. 8 and 9 are cross sectional end views of the arced coil of FIG. 7;

FIG. 10 is a cross sectional view of the arced coil of FIG. 7;

FIGS. 11 and 12 are a representation of an arced coil utilizing a uniform coil winding;

FIG. 13 is a graphical representation of the exponential decay of V_{coil}wherein the core of the coil sensor is not inserted into the coil; and

FIG. 14 is a graphical representation of the exponential decay of V_{coil}wherein the core of the coil sensor is fully inserted into the coil.

### BRIEF DESCRIPTION OF THE INVENTION

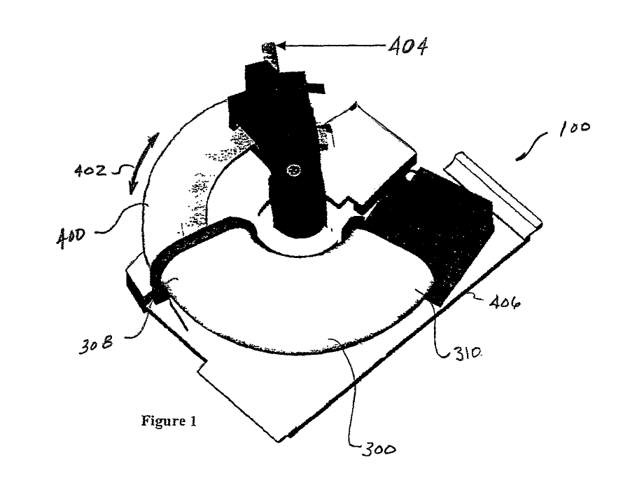

Referring to FIG. 1, a coil sensor is shown generally at 100. An inductive coil 300 is used to determine fuel level in a container by measuring the effective inductance of the coil sensor 100 obtained as a magnetic core 400 moves along arc 402 within the inductive coil 300. The further the core 400 is inserted into the inductive coil 300 the greater the effective inductance. By measuring this effective inductance, the relative position of the core 400 inside of the inductive coil 300 can be determined. The core 400 is connected mechanically to a floatation device (not shown) via a float arm 404 to determine the position of the flotation device in one axis. The float arm 404 with the floatation device in the fuel actuates the core 400 through the inside of the inductive coil 300. As the level of the fuel increases, the core 400 moves further into the inductive coil 300 increasing the effective inductance, and as the level of the fuel decreases, the core 400 moves further out of the inductive coil 300 decreasing the effective inductance.

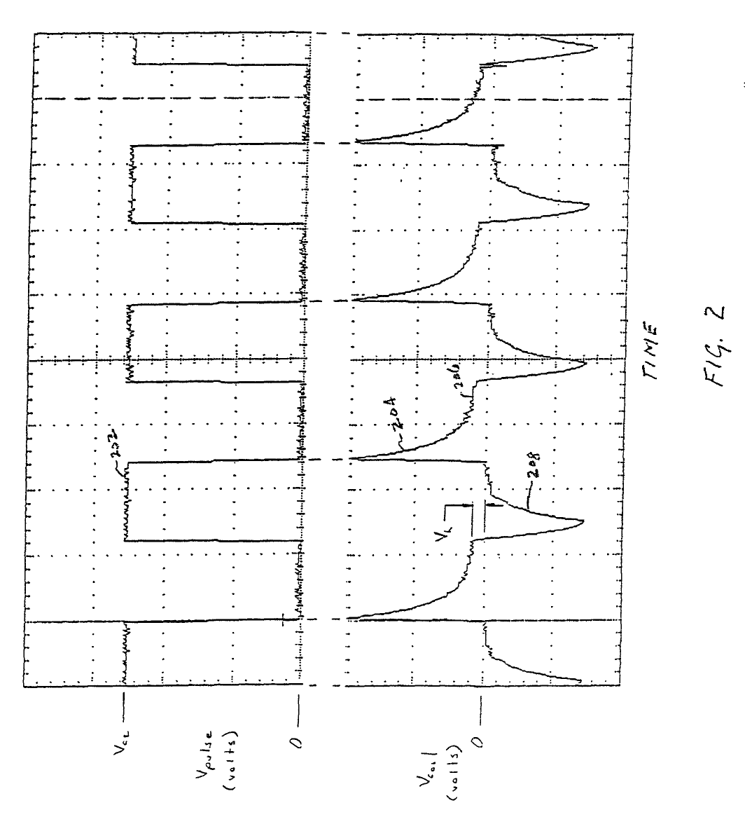

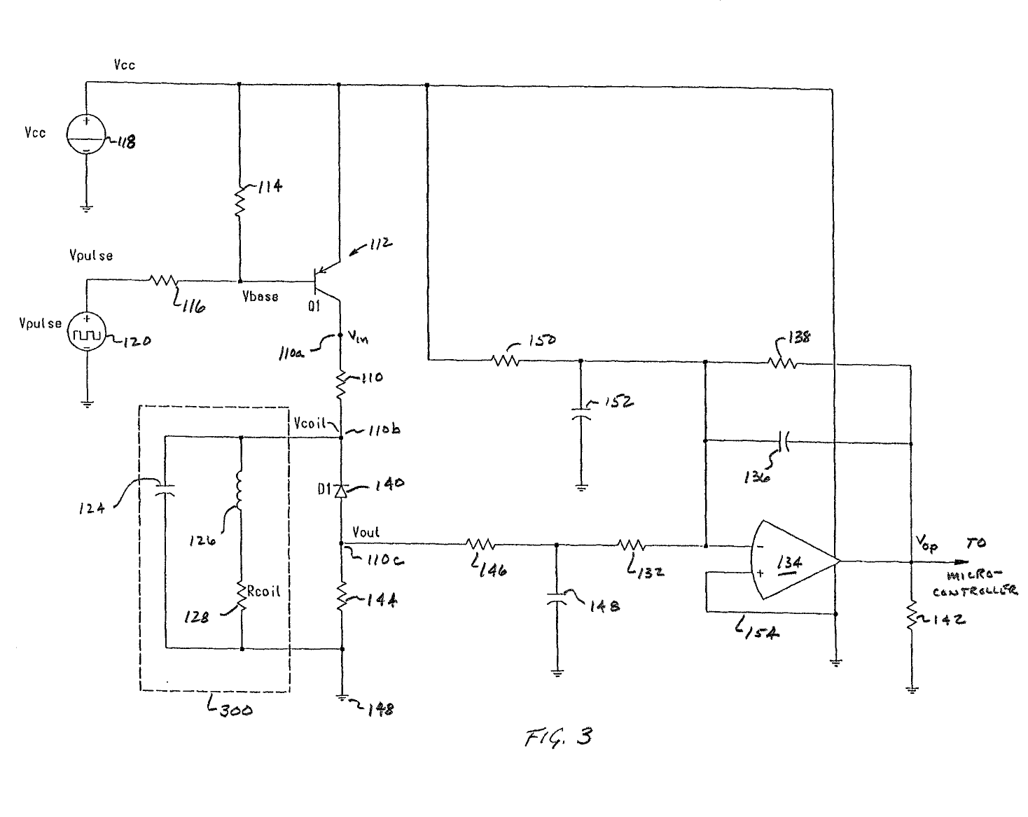

FIG. 3 shows a circuit in a Fuel Control Unit used to drive the inductive coil 300 and to measure the effective inductance. The coil sensor 100 is located remote from the electronics and connected thereto by a wiring harness. The effective inductance is determined by first exciting the inductive coil 300 by switching a voltage source with a square wave through a series resistor 110. The inductive coil 300 then responds to this by limiting current and creating a voltage waveform 204, 206, 208 similar to that shown in FIG. 2. The area under the curve 204, 206 of the voltage waveform correlates to charging the inductive coil 300. The area under the curve 208 of the voltage waveform correlates to the exponential decay of the current through the inductive coil 300. The decay is controlled by the circuit time constant, T_{L}. For an inductive circuit, the time constant is given by the inductance divided by the resistance (L/R). The aforesaid inductance is the variable inductance of the inductive coil 300 and the resistance is the resistance of the discharge resistor 144 plus the resistance of the coil itself (R_{coil} 128 in FIG. 3). A method of reading the effective inductance is to integrate the area under the curve 208 into a DC voltage level Vₒₚ. This DC voltage level can then be used by the Fuel Control Unit or sent out to other devices in the vehicle.

A square wave 202 excites the inductive coil 300. The square wave 202 is provided by a square wave oscillator circuit 120 or microcontroller output pin (shown as Vₚᵤₗₛₑ in FIG. 3). Transistor Q₁, 112 amplifies the square wave 202 and drives the inductive coil 300. Resistor 110 limits the current through the inductive coil 300 during charging. It is also chosen to be much larger than R_{coil} 128 so temperature changes in R_{coil} can be neglected. This allows the resistance of the coil to be neglected in determining the effective inductance of the coil to determine fuel level. Diode D₁ causes the circuit to analyze the negative portion 208 of the V_{coil} waveform. The negative voltage 208 is used rather than the positive voltage 204, 206 because a wiring harness short to either electrical ground or battery voltage will produce a zero output at the Opamp 134. Resistor 144 provides the aforesaid discharge resistance with current flowing through the diode 140 and determines the time constant for exponential decay in combination with the inductive coil (L_{coil}/R₁₄₄). The Opamp 134 acts as an integrator to provide an analog voltage output, Vₒₚ, that corresponds to fuel level, which is read by a microcontroller (not shown). The combination of resistor 146 and capacitor 148 make a low pass filter. Resistors 146 and 132 are the integrator input resistance. Resistor 138 sets the integrator gain as R₁₃₈/(R₁₄₆+R₁₃₂). Resistor 150 is used to set the offset voltage to the integrator 134.

A method of measuring R_{coil} is to measure the voltage across the coil, V_{coil}. V_{coil} is an exponential charging and discharging voltage through the coil 300 as shown by V_{coil} in FIG. 2. In order to measure V_{coil}, the square wave 202 used to measure the effective inductance is halted temporarily and Q₁ in FIG. 3 remains turned “on” until the coil 300 is fully charged. The 8.2 kHz square wave on Vₚᵤₗₛₑ is stopped and Vₚᵤₗₛₑ is set to 5 Volts to turn Q₁ on. Once the coil is fully charged, the voltage across the coil is given by

$${V}_{coil} = \frac{{R}_{coil}}{{R}_{coil} + {R}_{110}} \times {V}_{cc} \qquad ( 1 )$$

as shown in FIG. 3. If resistor 110 and V_{cc} do not vary with temperature, then R_{coil} would be the only temperature dependent variable. To accomplish this, Resistor 110 is chosen to be a discrete resistor with a low temperature coefficient as is common with carbon resistors. The voltage difference between V_{cc} and Vᵢₙ is negligible for low currents flowing through Q₁. V_{cc} can vary somewhat with temperature but this can be neglected if the ADC is also powered by V_{cc}.

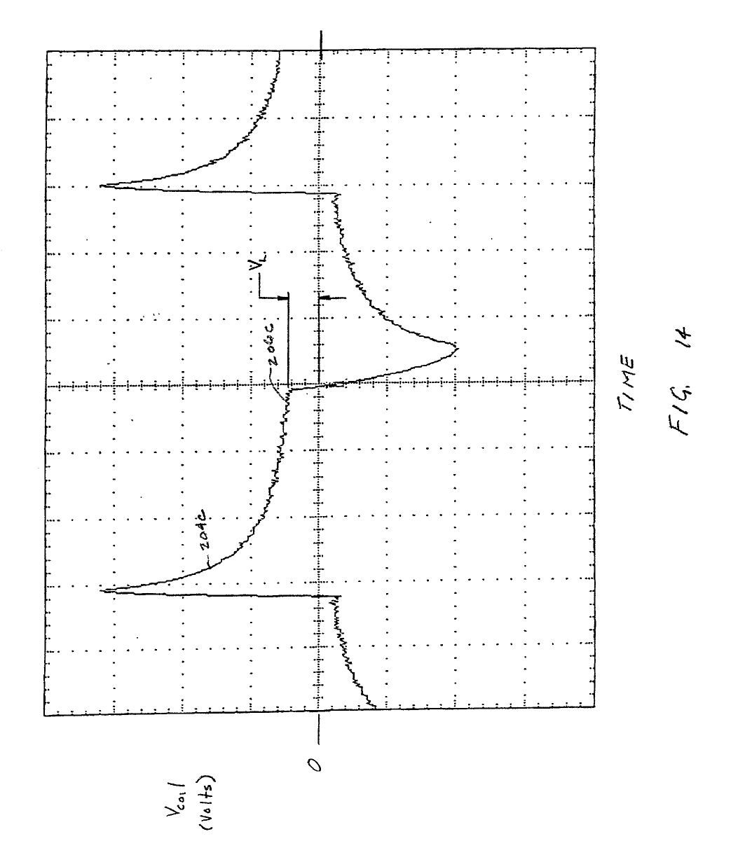

As seen in FIGS. 2 and 3, Vᵢₙ is alternately energized and de-energized at 110a by a 8.2 kHz square wave pulse, Vₚᵤₗₛₑ, 202 having values of zero volts and V_{cc} volts generated by a microcontroller 120. When Vₚᵤₗₛₑ is zero (Q₁ on), the inductor 126 is charging and V_{coil} decays exponentially as seen at 204. Depending upon the charging time constant (set by resistor 110) of the coil sensor 300, as seen at 206, V_{coil} will decay to a substantially constant value V_{L} after a prescribed time interval, tₒ. When Vₚᵤₗₛₑ is positive (Q₁ off), V_{Coil} grows exponentially as the current through the coil exponentially decays as seen at 208 in FIG. 2. The exponential decay of current is controlled by the time constant T_{L}. It will be appreciated from FIGS. 13 and 14 that as the core 400 moves into and out of the inductive coil 300, the time constant, T_{L} of the coil sensor 100 changes and the rate of the exponential decay will change. Thus, FIG. 13 is representative of the sensor 100 charging when the core 400 is substantially out of the inductive coil 300 and FIG. 14 is representative of the sensor 100 charging when the core 400 is more fully encompassed by the inductive coil 300.

The electronic circuit of FIG. 3 that drives the sensor 100 calibrates the sensor at empty and full when initially installed in the fuel tank. The empty reading is taken once the unit is installed in the tank. The tank is then inverted and the full reading is then taken. This calibration will reduce the variation in the output signal due to coil and core variations. It also allows the floatation device to be set so that it rests on the tank bottom at empty and the unmeasurable fuel will be determined by the amount of fuel needed to raise the float off of the bottom tank.

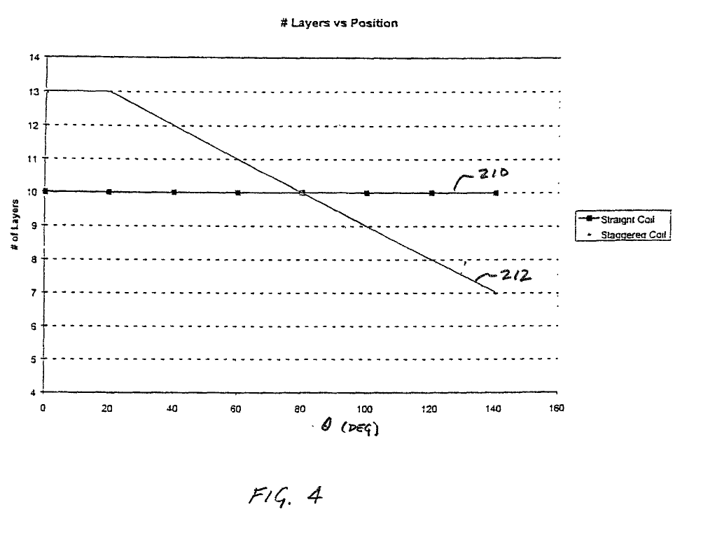

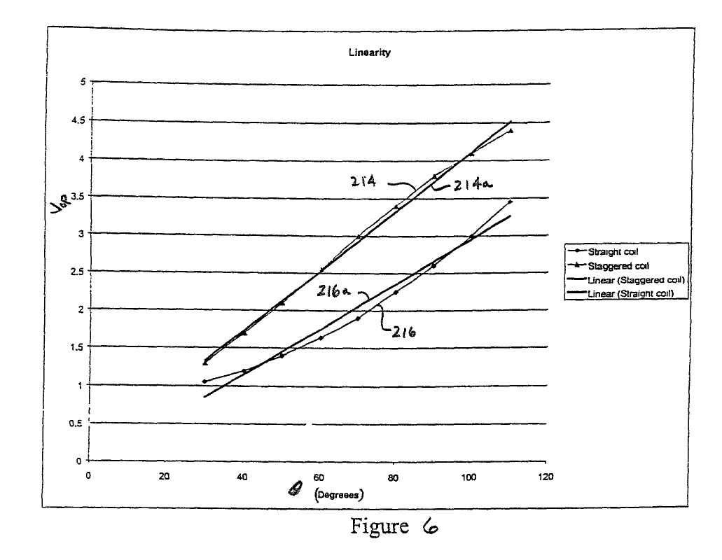

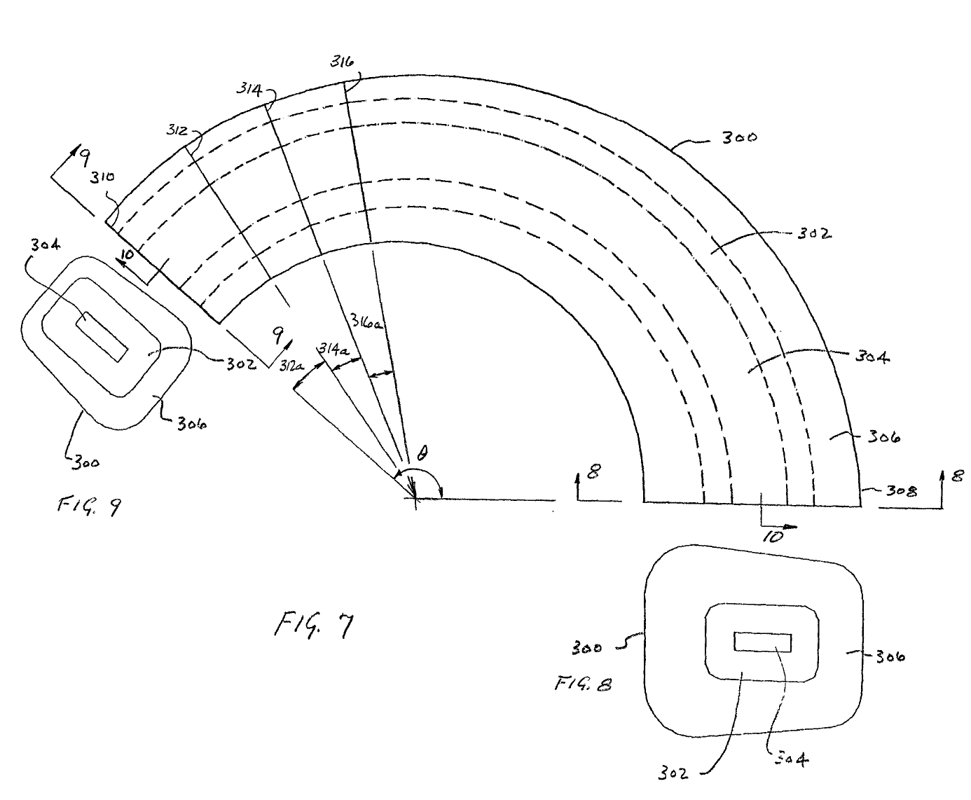

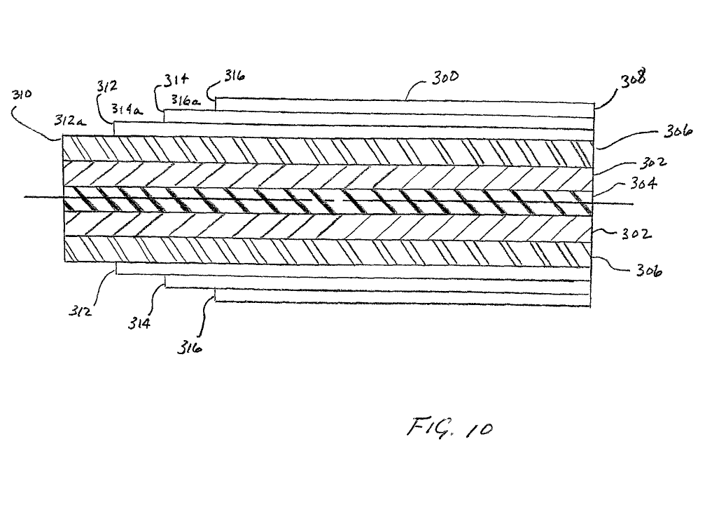

Referring now to FIGS. 4, 7, 8 and 9, the staggered inductive coil 300 comprises a bobbin 302 including a cavity 304 defined therein. The bobbin 302 comprises a nonmagnetic material such as molded plastic. The core 400 of FIG. 1 enters the cavity 304 at the end of the inductive coil 300 designated by the reference numeral 308. A wire 306 is wrapped or spooled continuously around the bobbin 302 at a prescribed pitch, pₒ, beginning at 310 and extending to the opposing end 308 of the inductive coil 300; or conversely beginning at 308 and extending to 310. Such wrapping of the wire around the bobbin 302 is such as to result in at least one layer of wire 306 extending over a first portion of the bobbin 302. For purposes of clarity, it is to be understood that a turn is a single complete revolution about the bobbin 302 by the wire 306 and that a layer of the coil arises due to multiple adjacent turns of the wire 306 about the bobbin 302 extending along a prescribed portion of the bobbin 302. Pitch is the number of turns per unit length along bobbin 302. The first portion of the inductive coil 300 may extend over the entire length of the bobbin 302 by terminating at 310 or over a portion less than the entire length of the bobbin 302 by terminating for example at 312. At the end of the wrapping of the first layer of the wire 306, the wrapping continues, returning to the starting point of the wrapping yielding a second layer. The return of the wrapping to the starting point may be at the aforesaid prescribed pitch, pₒ, or at a second pitch, pᵣ, having a lower or higher value than pₒ. For example, the return of the wrapping to the starting point may be a rapid transfer return wherein pᵣ is much lower than pₒ. The wrapping of the wire 306 about the bobbin 302 continues still further to the point 312 or to the point 314 whereby the wire 306 encircles the bobbin 302 over a second portion spanning less than the previous layer. The aforesaid wrapping of the wire 306 about the bobbin 302, can be continued for a plurality of repetitions, resulting in the staggered inductive coil 300 of FIGS. 7, 8, 9 and 10. As best understood from FIGS. 7 and 10, the angular spans 312a, 314a, 316a between the terminations of subsequent wrappings of the wire 306 about the inductive coil 300 at 312, 314 and 316 can be made smaller and smaller such that the staggered coil assumes the profile of an essentially truncated cone.

The number of layers of wire 306 as a function of the angular span of the layer in the staggered wound inductive coil 300 is shown in FIG. 4 at 212. A constant number of layers (for example ten) over the extent of the bobbin 302 is shown at 210 for a straight wound coil. It will be appreciated that the aforesaid winding of the wire 306 can be accomplished by winding a prescribed constant number of layers first before effecting the staggering of the wire windings. As an example, FIG. 4 shows seven layers first wound over the extent of the inductive coil 300 prior to effecting the staggered windings. It will also be appreciated that two or more constant layers of wire 306 may be effected between any two staggered layers.

Thus, the staggered inductive coil 300 uses a greater number of turns of the wire 306 at the end of the inductive coil 300 where the core 400 first enters the cavity 304 and a progressively lesser number of turns of the wire 306 as one moves along the length of the inductive coil 300, resulting in a cone-like (or truncated cone-like) configuration of the wire 306 wrapped around the bobbin 302 (FIG. 10). This increases the effective inductance of the coil sensor 100. The point of first entry of the core into the cavity 304 is designated by the reference numeral 308 in FIGS. 1 and 7. In FIG. 10 it can be seen that successive layers of the coil include at least one boundary thereof in common at 308.

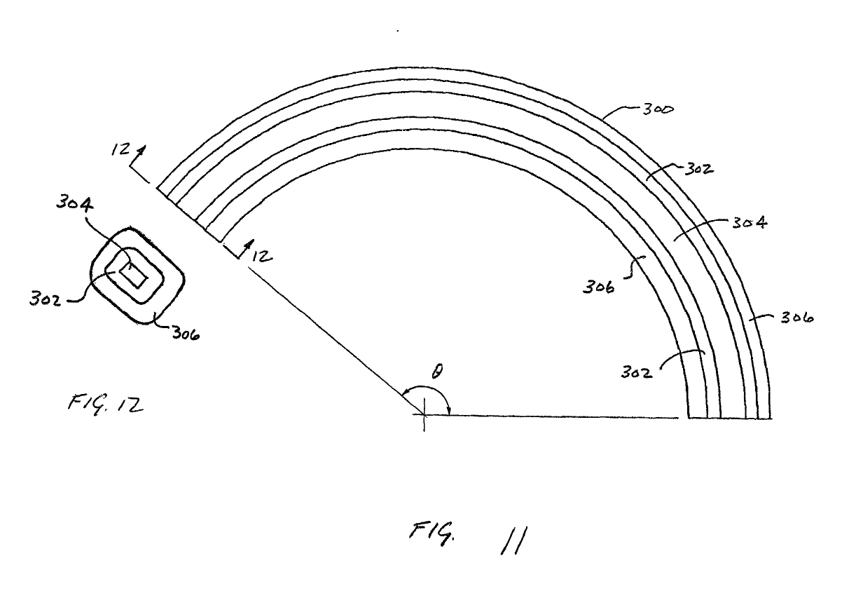

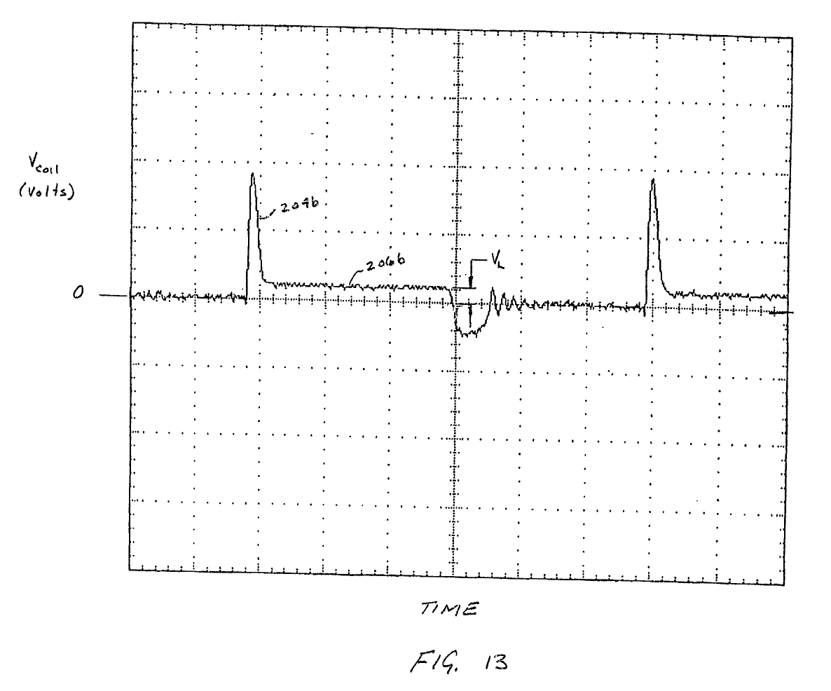

FIGS. 11 and 12 are a representation of an arced coil utilizing a uniform coil winding. In FIGS. 7 and 8, an arced inductive coil 300 is shown, however the methods and apparatus of this invention are equally applicable to a straight inductive coil 300. The arc of the inductive coil 300 shown in FIGS. 7 and 11 is, by way of exemplification and not limitation, approximately 140 degrees.

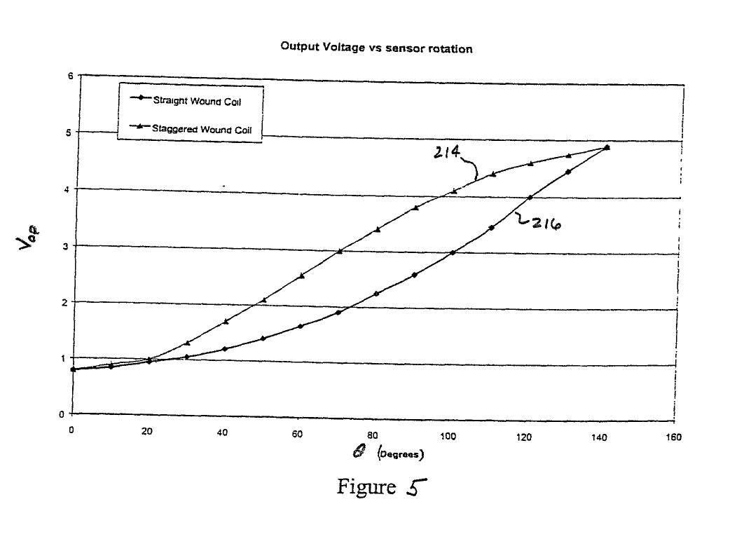

The improvement in the linearity of the effective inductance for a staggered coil vs. a straight coil can be seen in actual test results. FIG. 5 shows output voltage, Vₒₚ, from the sensor circuit for a staggered wound coil at 214 and for a straight wound coil at 216, for the same total number of turns.

FIG. 6 shows the improvement in the linearity of the output voltage vs. the position of the core 400 within the staggered coil and straight coil for the data range of 30 to 110 degrees of rotation of FIG. 5, which is the operating range of the sensor 100. In FIG. 6, the linearization of the output voltage (for example by least squares fitting) for the staggered coil is seen at 214a and results in the equation of a straight line of:

y=0.03980θ+0.1453 (2)

with a residual of R₂=.9963; and for the straight coil is seen at 216a resulting in a straight line of:

y=0.03θ−0.0467 (3)

with a residual of R²=0.9757, where y is the output voltage of the sensor 100, Vₒₚ, and θ is the angular position of the core 400 within the cavity 304 of the inductive coil 300.

While preferred embodiments have been shown and described, various modifications and substitutions may be made thereto without departing from the spirit and scope of the invention. Accordingly, it is to be understood that the present invention has been described by way of illustration only, and such illustrations and embodiments as have been disclosed herein are not to be construed as limiting the claims.

What is claimed is:

1. An inductive coil element comprising:
a bobbin; and
a coil encircling the bobbin defining thereby at least one layer of the coil, the at least one layer of the coil extending over a first portion of the bobbin;
wherein at least one other layer of the coil extends over a second portion of the bobbin less than the first portion of the bobbin.

2. The inductive coil element as set forth in claim 1 wherein the bobbin comprises a nonmagnetic material.

3. The inductive coil element as set forth in claim 1 wherein the bobbin defines a cavity therein receptive of a magnetic core.

4. The inductive coil element as set forth in claim 1 wherein the coil comprises a wire.

5. The inductive coil element as set forth in claim 1 wherein the cavity comprises an air core.

6. The inductive coil element as set forth in claim 1 wherein the first portion of the bobbin extends over the extent of the bobbin.

7. The inductive coil element as set forth in claim 6 wherein a second layer of the coil extends over the extent of the bobbin.

8. A method of linearizing the change in the effective inductance of an inductive coil element including a bobbin with respect to the position of a magnetic core within a cavity defined within the bobbin, the method comprising:
encircling the bobbin with a coil defining thereby at least one layer of the coil extending over a first portion of the bobbin, wherein at least one other layer of the coil extends over less than the first portion of the bobbin.

9. The method as set forth in claim 8 wherein encircling the bobbin with a coil comprises encircling the bobbin with a wire.

10. A method of constructing an inductive coil element including a bobbin, the method comprising:
beginning at a first location on the bobbin, encircling the bobbin with a coil defining thereby at least one layer of the coil, the at least one layer of the coil extending over a first portion of the bobbin;
wherein at least one other layer of the coil extends over a second portion of the bobbin less than the first portion of the bobbin.

11. The method as set forth in claim 10 wherein encircling the bobbin with a coil comprises encircling the bobbin with a wire.

12. The method as set forth in claim 10 wherein encircling the bobbin with a coil comprises encircling the bobbin with a coil at a first pitch.

13. The method as set forth in claim 12 further comprising:
at a second location on the bobbin, terminating encircling the bobbin at the first pitch; and
encircling the bobbin at a second pitch.

14. The method as set forth in claim 13 wherein encircling the bobbin comprises beginning at the second location on the bobbin, encircling the bobbin with a coil defining thereby at least one layer of the coil, the at least one layer extending over a first portion of the bobbin;
wherein at least one other layer of the coil extends over a second portion of the bobbin less than the first portion of the bobbin.

15. A fluid level sensor comprising:
an inductive coil element including a bobbin having a cavity therein receptive of a core linked to a fluid in a container and a coil encircling the bobbin defining thereby at least one layer of the coil, the at least one layer extending over a first portion of the bobbin;
wherein at least one other layer of the coil extends over a second portion of the bobbin less than the first portion of the bobbin; and
a circuit connected to the inductive coil element including means for alternately charging and discharging the inductive coil element generating thereby a signal indicative of the level of the fluid in the container.

16. The inductive coil element as set forth in claim 15 wherein the bobbin comprises a nonmagnetic material.

17. The inductive coil element as set forth in claim 15 wherein the bobbin defines a cavity therein receptive of a magnetic core.

18. The inductive coil element as set forth in claim 15 wherein the coil comprises a wire.

19. The inductive coil element as set forth in claim 15 wherein the cavity comprises an air core.

20. The inductive coil element as set forth in claim 15 wherein the first portion of the bobbin extends over the extent of the bobbin.

21. The inductive coil element as set forth in claim 20 wherein a second layer of the coil extends over the extent of the bobbin.

22. An inductive coil element comprising:
a bobbin; and
a coil encircling the bobbin defining thereby at least one layer of the coil, the at least one layer of the coil extending over a first portion of the bobbin;
wherein at least one other layer of the coil overlaps the first layer and extends over a second portion of the bobbin less than the first portion of the bobbin;
wherein the at least one layer of the coil and the at least one other layer of the coil include at least one boundary thereof in common.

23. The inductive coil element as set forth in claim 22 wherein the bobbin comprises a nonmagnetic material.

24. The inductive coil element as set forth in claim 22 wherein the bobbin defines a cavity therein receptive of a magnetic core.

25. The inductive coil element as set forth in claim 22 wherein the coil comprises a wire.

26. The inductive coil element as set forth in claim 22 wherein the cavity comprises an air core.

27. The inductive coil element as set forth in claim 22 wherein the first portion of the bobbin extends over the extent of the bobbin.

28. The inductive coil element as set forth in claim 27 wherein a second layer of the coil extends over the extent of the bobbin.

29. The inductive coil element as set forth in claim 1 wherein the at least one other layer of the coil overlaps the first layer.

30. The inductive coil element as set forth in claim 1 wherein the at least one layer of the coil and the at least one other layer of the coil include at least one boundary thereof in common.

31. The method as set forth in claim 10 wherein the at least one other layer of the coil overlaps the first layer of the coil and wherein the at least one layer of the coil and the at least one other layer of coil include at least one boundary thereof in common.
